(19) United States
(12) Patent Application Publication
(10) Pub. No.: US 2013/0048069 A1
(43) Pub. Date: Feb. 28, 2013

(54) Solar Cell Having Selective Emitter

(71) Applicant: Li-Karn Wang, Taipei (TW)

(72) Inventor: Li-Karn Wang, Taipei (TW)

(73) Assignee: NATIONAL TSING HUA UNIVERSITY, Hsinchu (TW)

(21) Appl. No.: 13/396,922

(22) Filed: Feb. 15, 2012

(30) Foreign Application Priority Data
Aug. 30, 2011 (TW) 100131204

(51) Int. Cl. H01L 31/0236

(52) U.S. Cl. 136/256

(57) ABSTRACT

The present invention provides a solar cell having a selective emitter structure on a doped silicon substrate. The silicon substrate is mono-crystalline or multi-crystalline. A plurality of trenches are formed at the illuminated side of the silicon substrate. After one-time diffusion doping, the silicon substrate is processed through selective etching. The region outside the trenches obtains a lower doping concentration, while the region of the trenches remains to be highly doped. Thus, a selective emitter structure is formed.

### TECHNICAL FIELD OF THE INVENTION

The present invention relates to a solar cell; more particularly, relates to forming a plurality of trenches on a silicon substrate through etching; a P-N junction through one-time electronic doping; and a selective emitter through selective etching.

### DESCRIPTION OF THE RELATED ARTS

A solar cell uses a p-type solar grade silicon substrate to form a p-n junction through phosphorous diffusion, where the silicon substrate has a resistivity between 1 and 3 Ω-cm and a sheet resistance of about 60 Ω/sq after forming the p-n junction. The sheet resistance is obtained at a preferred value through specific adjustment. If the doping concentration for an n-type layer is too high after the diffusion, the sheet resistance will be small. Although it means that the conductivity of the n-type layer is very high and the contact resistance between the front contact and the semiconductor is very low, the recombination rate of carriers at the near-surface region is increased and the open-circuit voltages and short-circuit current are both lowered. On the contrary, if the sheet resistance is very high, the conductivity will be lowered and the contact resistance between the front contact and the semiconductor is increased to hinder the increase in fill factor.

A selective emitter is used to reduce the contact resistance between the front contact and the semiconductor and to remain a preferred lateral conductivity of a non-electrode region. This kind of selective emitter has a higher doping concentration in a local region (under the metal front contact) and a lower doping concentration in the other region so as to obtain a lower electrode-semiconductor contact resistance and a preferred short-wavelength optical response.

Up until now, methods for fabricating a solar cell having the selective emitter include the following:

The first method uses a phosphorous-containing paste for being screen-printed to result in a patterned film, i.e., the paste is only printed at a corresponding region of the front contact. Then, the film is used as a diffusion source for diffusing phosphorous into a silicon substrate at a high temperature. At the same time, a vapor phase is formed to obtain a heavily-doped near-surface region at the place printed with the paste on the substrate, while near-surface region at the other places on the substrate are lightly doped. Although this method forms the heavily- and lightly-doped regions at a time, its high-temperature diffusion has to be well-controlled and thus is not fit for mass production.

The second method processes a heavy doping process all over the surface at the illuminated side of a silicon substrate to form a heavily-doped diffusion layer. Then, a barrier is formed through screen-printing for obtaining lightly- and heavily-doped diffusion regions with the coordination of an etching-back process. This method requires uniform etching-back at a large area with high complexity, which is not fit for mass production and may even harm readily-made textured surface during etching-back. Besides, the solar cell thus made requires high-precision aligning device for printing silver paste on the heavily-doped diffusion region. A light-induced plating process is required to increase the thickness of silver wires and reduce resistance of the silver wires. Hence, this method is not yet fit for mass production.

The third method processes a light-doping process all over the surface at the illuminated side of a silicon substrate to form a lightly-doped diffusion layer. Then, a phosphorous-containing silver paste is used to print a front contact through screen-printing. At last, the front contact is formed through a common industrial practice of co-firing (with back contact formed), and at the same time, phosphorous is diffused into the lightly-doped diffusion layer to form heavily- and lightly-doped diffusion regions simultaneously. The major advantage of this method is that only silver paste used for common industrial mass production is needed to be replaced by the dopant-containing type of metal paste for obtaining the front contact. However, silver has a faster diffusion rate than phosphorous during co-firing so that the leakage current is worsened and therefore advantages of the selective emitter are balanced off.

The fourth method processes a light-doping process all over the surface at the illuminated side of a silicon substrate to form a lightly-doped diffusion layer. Then, trenches are formed by a laser scribing technique at the region of front contact and a heavy-doping is processed to obtain a heavily-doped diffusion layer therein. Then, the front contact is formed by filling the trenches with a metal through plating. The trenches may have a certain depth to form a buried contact structure which combines with features of selective emitter. In FIG. 3, a p-type silicon substrate 30 having a textured surface 32 exemplifies a buried contact solar cell. One method for fabricating such a solar cell is to form a lightly-doped n-type layer 36 and an anti-reflective layer 33 first on a surface at the illuminated side of the silicon substrate. Then, a plurality of trenches are formed through laser scribing, followed by a heavy-doping process to form a heavily-doped layer 34, i.e. n⁺-type layer, at the near-surface region of the trenches. Then, through plating, a metal is formed inside the trenches to form buried contact 38. This kind of solar cell is usually pasted with aluminum paste at the non-illuminated side through screen-printing to form a back contact 39 and a back surface field 37 after being sintered. However, because extra laser devices, doping devices and plating devices are required, this method is not compatible to modern mass-production techniques.

Obviously in most prior arts for fabricating a solar cell having both a selective emitter and a buried contact, extra devices are required, or complicated procedures are required, and therefore mass production is hindered. Hence, the prior arts do not fulfill all users' requests on actual use.

### SUMMARY OF THE INVENTION

The main purpose of the present invention is to fabricate a silicon solar cell, wherein the solar cell has a selective emitter structure.

To achieve the purpose above, the present invention is a solar cell having a selective emitter, wherein the solar cell is fabricated by using a pre-doped silicon substrate; the silicon substrate is a mono-crystalline silicon substrate or a multi-crystalline silicon substrate; a plurality of trenches are formed on a surface at the illuminated side of the silicon substrate; the surface at the illuminated side of the silicon substrate comprises a first surface region and a second surface region; both of the first surface region and the second surface region have a doping polarity opposite to the silicon substrate; the first surface region comprises a first surface and a first doped layer; the first surface is a surface of region of the trenches at the illuminated side of the silicon substrate; the second surface region comprises a second surface and a second doped layer; the second surface is a surface of region outside the trenches at the illuminated side of the silicon substrate; after the surface at the illuminated side of the silicon substrate having the trenches is processed through diffusion to result in a heavily-doped layer all over the near-surface region of the silicon substrate, a barrier is pasted on the surface of region of the trenches; the surface of region outside the trenches is etched to a certain depth through wet chemical etching to obtain a second doped layer having a lower doping concentration; and the surface of region of the trenches remains highly doped to obtain the first doped layer having a higher doping concentration. Accordingly, a structure of selective emitter is obtained.

### BRIEF DESCRIPTION OF THE DRAWINGS

The present invention will be better understood from the following detailed description of the preferred embodiments according to the present invention, taken in conjunction with the accompanying drawings, in which

FIG. 1A to FIG. 1F are the flow views showing the fabrication of a preferred embodiment according to the present invention;

FIG. 2 is the view showing the silicon substrate obtained after the process of wet chemical etching; and

FIG. 3 is the view of a prior art.

### DESCRIPTION OF THE PREFERRED EMBODIMENT(S)

The following description of the preferred embodiments is provided to understand the features and the structures of the present invention.

The present invention is a solar cell having a selective emitter, which is made of a mono-crystalline or multi-crystalline doped silicon substrate. At first, a plurality of trenches are formed on a front surface of the doped silicon substrate, where the trenches have depths between 0.5 micrometers (μm) and 100 μm. Then, the front surface is textured, followed by a diffusion process. The diffusion process produces a heavily-doped layer with a doping polarity opposite to that of the silicon substrate at the near-surface region of the trenches and the near-surface region outside the trenches. Then, the region outside the trenches is etched to a certain depth inside the silicon substrate to turn the corresponding surface region into a lightly-doped diffusion layer so that a selective emitter having heavy and light concentrations is formed. That is, the surface of the region of the trenches has a heavily-doped diffusion layer and the surface of the region outside the trenches has a lightly-doped diffusion layer.

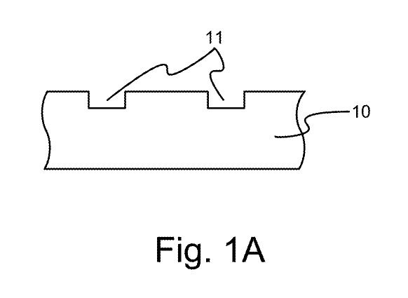

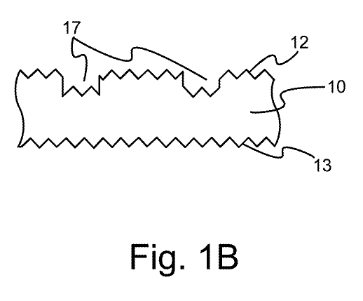

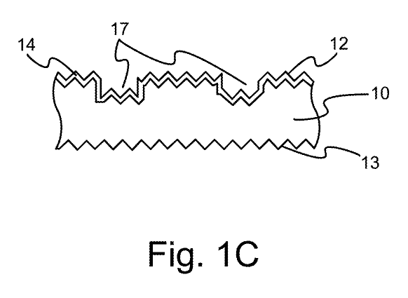

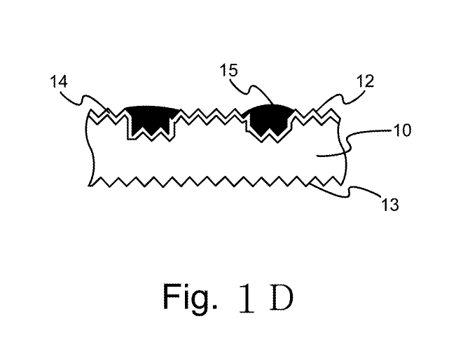

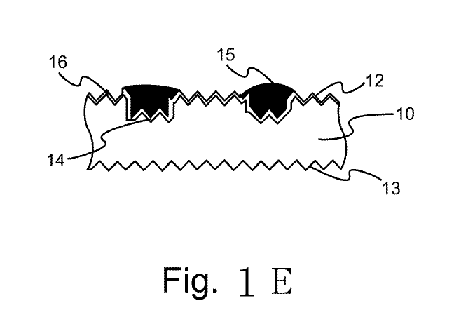

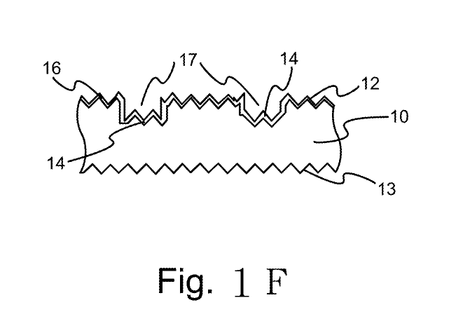

Please refer to FIG. 1A to FIG. 1F, which are flow views showing fabrication of a preferred embodiment according to the present invention. As shown in the figures, at first, a p-type or n-type doped silicon substrate 10 is obtained and a plurality of trenches 11 are formed on its surface (FIG. 1A). Therein, the trenches 11 are formed by pasting a material of barrier layer on the silicon substrate 10 through screen printing. A part of the front surface of the silicon substrate 10 is covered by the material of barrier layer and the other part of the front surface of the silicon substrate 10 is not covered by the material of barrier layer. The back surface of the silicon substrate 10 is totally covered by the material of barrier layer. Through wet chemical etching, the part of the front surface of the silicon substrate 10 covered by the material of barrier layer is not etched and the other part of the front surface of the silicon substrate 10 not covered by the material of barrier layer is etched to form the trenches 11. The back surface of the silicon substrate 10 is not etched for being totally covered by the material of barrier layer.

Then, the silicon substrate 10 is washed to remove the material of barrier layer and is textured (FIG. 1B). A first textured surface 12 and a second textured surface 13 are formed on the front surface and the back surface of the silicon substrate 10, respectively. Therein, the first textured surface 12 has a micro-structure of pyramid-like protrusions, which has a light trapping function. Texture is also formed inside the trenches 17. In another example, the second textured surface 13 having a light trapping function is not formed on the back surface. In a further example, texture for light trapping is not formed inside the trenches 17.

Then, the silicon substrate 10 is processed through diffusion of doping element to form a heavily-doped layer 14 on the front surface, with a doping polarity opposite to that of the silicon substrate 10 (FIG. 1C). After removing derived material obtained in the diffusion process, a material of barrier layer is pasted only in the region of the trenches 17 on the front surface through aligned screen printing to form the barrier layer 15 covering the trenches 17 (FIG. 1D).

Then, the silicon substrate 10 is sunk in a chemical etching solution to remove a tiny portion of the region outside the trenches on the surface of the silicon substrate 10. Thus, the thickness of the heavily-doped layer 14 on the region outside the trenches becomes smaller to form a lightly-doped layer 16 on the region outside the trenches (FIG. 1E). The heavily-doped layer 14 still remains on the surface of the region of the trenches. Because only a tiny portion of the region outside the trenches is etched away through wet chemical etching, most of the first textured surface 12 keeps its original outlook. In addition, owing to being sunk in the chemical etching solution, a tiny portion of the back surface of the silicon substrate 10 is also etched away, while the second textured surface 13 of the back surface approximately keeps its original outlook. In another example, the back surface of the silicon substrate 10 is covered with a material of barrier layer for not being etched.

At last, the barrier layer 15 over the trenches are washed out to form a plurality of trenches 17 on the front surface of the silicon substrate 10, where the heavily-doped layer 14 is formed at the near-surface region of the trenches 17 of the silicon substrate 10 and the lightly-doped layer 16 is formed at the near-surface region outside the trenches of the silicon substrate 10.

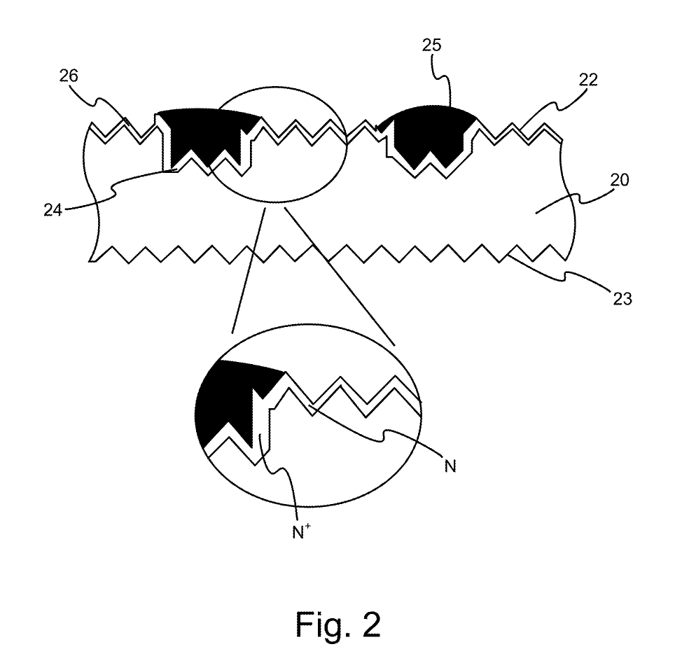

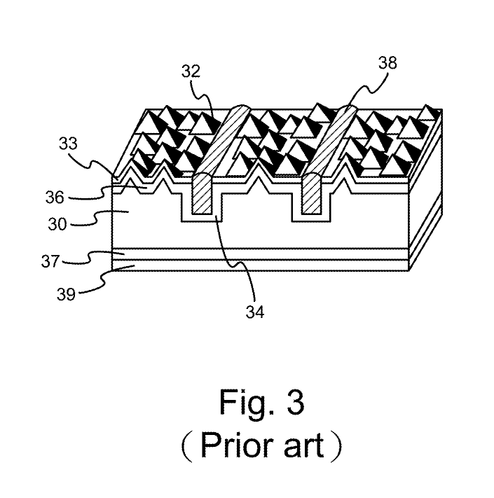

Please refer to FIG. 2, which is a view showing a p-type silicon substrate 20 obtained after process of wet chemical etching. As shown in the figure, the silicon substrate 20 has a barrier layer 25 pasted in trenches on the front surface of silicon substrate 20. After processed with wet chemical etching, most of the textured surface 22 on the front surface of the silicon substrate 20 and another textured surface 23 on the back surface of the silicon substrate 20 keep their outlooks of texturization. Region outside the trenches on the front surface has a lightly-doped n-type layer 26; while region of the trenches on the front surface has a heavily-doped n⁺-type layer 24 (as shown in FIG. 1F). Then, an anti-reflective layer is coated (ARC coating) or a passivation layer is deposited beforehand. The anti-reflective layer is made of silicon nitride, zinc oxide, tin oxide, tin indium oxide or silicon dioxide. Then, a front contact with a metal-containing paste is pasted into the trenches on the front surface; and, a back contact with a metal-containing paste is pasted on the back surface. Then, the front contact and the back contact are sintered to obtain good electric contact between the contacts and the silicon substrate. After the back contact is sintered, a back surface field is formed on the back surface of the silicon substrate. In another example, the back surface field is formed by coating a doped layer on the back surface of the silicon substrate. The doped layer contains amorphous silicon, crystalline silicon, amorphous silicon germanium compound or crystalline silicon germanium compound. In a further example, the back surface field on the back surface of the silicon substrate is formed by diffusing a doping element into the near-surface region of the backside of the silicon substrate through a high-temperature diffusion process. The doping element is a III A group element or a V A group element. Specifically speaking, if the silicon substrate is p-type, the doping element is a III A group element; and, if the silicon substrate is n-type, the doping element is a V A group element.

The front and back contacts can be formed at the same time through co-firing. Or, in another example, the front contact is sintered at first and the back contact is then pasted and sintered.

In another embodiment of the present invention for fabricating selective emitter, a plurality of trenches are formed on the front surface of a doped silicon substrate that is textured in advance to at least result in a front surface with a pyramid-like structure or any other type of roughness that has an anti-reflection function. A barrier layer is pasted on the front surface of the silicon substrate to resist chemical etching for forming a pattern with openings. The barrier layer can be pasted on the back surface of the silicon substrate, too. Then, through wet chemical etching, a plurality of trenches are formed at the positions of the openings on the front surface of the silicon substrate. Then, a lightly- and a heavily-doped layers are formed and the front and the back contacts are fabricated following the same process as in the first embodiment of the present invention.

In another example, after forming the trenches on the front surface of the doped silicon substrate, diffusion of a doping element is processed to form a heavily-doped layer on the front surface of the silicon substrate. The doped layer has the same polarity as the silicon substrate and has a larger doping concentration than the silicon substrate. A barrier layer is then pasted on the surface region in the trenches on the front surface of the silicon substrate and, then, a small portion of the region outside the trenches on the front surface of the silicon substrate is etched away to a small depth through wet chemical etching to form a lightly-doped layer and to further form a doped layer having the same polarity as the silicon substrate and a larger doping concentration than the silicon substrate. The surface of region of the trenches is protected by the material of barrier layer and thus remains to have an intact heavily-doped layer. After the lightly- and heavily-doped regions are formed on the front surface of the silicon substrate, an anti-reflective layer, even together with a passivation layer, is coated. Then, a front contact is pasted and both a back contact and a back surface field are formed on the back surface of the silicon substrate.

The solar cell fabricated according to the present invention may or may not have a passivation layer on the back surface of the silicon substrate. In fabricating the solar cell with a passivation layer, after the lightly- and heavily-doped layers are formed on the front surface of the silicon substrate, the passivation layer is formed on the back surface of the silicon substrate, where the passivation layer is made of silicon dioxide, silicon nitride, silicon oxynitride, aluminum oxide, aluminum nitride or amorphous silicon.

Thus, a plurality of trenches are formed on the surface at the illuminated side of the silicon substrate. After one-time diffusion doping with an element, selective etching is processed to form a lightly-doped region outside the trenches and region of the trenches remains to be heavily doped, thus forming a selective emitter structure. Besides, if the trenches have large enough depths, say above 30 μm, the type of solar cells accordingly invented are buried contact solar cells. Thus, the present invention is fit for pass production with high yield and without extra high-cost facilities and complex procedure. Accordingly, the present invention fabricates a solar cell at a low cost through an easy procedure. The solar cell has high performance with a selective emitter structure or even with a buried contact.

To sum up, the present invention is a solar cell having a selective emitter, wherein a plurality of trenches are formed on a surface at the illuminated side of a silicon substrate and, after one-time diffusion doping with an element, selective etching is conducted to form a lightly-doped region outside the trenches while near-surface region of the trenches remains heavily doped for forming a selective emitter structure; and, if the trenches have large enough depths, structure and function of a buried contact are also obtained.

The preferred embodiments herein disclosed are not intended to unnecessarily limit the scope of the invention. Therefore, simple modifications or variations belonging to the equivalent of the scope of the claims and the instructions disclosed herein for a patent are all within the scope of the present invention.

What is claimed is:

1. A solar cell having a selective emitter,
wherein said solar cell is obtained by using a doped silicon substrate and said silicon substrate is selected from a group consisting of a mono-crystalline silicon substrate and a multi-crystalline silicon substrate;
wherein a plurality of trenches are obtained on a surface at an illuminated side of said silicon substrate; each of said trenches has a depth between 0.5 micrometer (μm) and 100 μm; said surface at said illuminated side of said silicon substrate comprises a first surface region and a second surface region; both of said first surface region and said second surface region have thin doped layers on said silicon substrate; said first surface region comprises a first surface and a first doped layer; said first surface is a surface of region of said trenches at said illuminated side of said silicon substrate; said second surface region comprises a second surface and a second doped layer; and said second surface is a surface of region outside said trenches at said illuminated side of said silicon substrate; and
wherein, after said surface at said illuminated side of said silicon substrate having said trenches is processed through diffusion of heavy doping, a barrier is pasted on said surface of region of said trenches; said surface of region outside said trenches is etched to a certain depth through wet chemical etching to obtain said second doped layer having a lower doping concentration; and
said surface of region of said trenches remains highly doped to obtain said first doped layer having a higher doping concentration.

2. The solar cell according to claim 1,
wherein a front contact is obtained in said trenches at said illuminated side of said silicon substrate.

3. The solar cell according to claim 1,
wherein an anti-reflective layer is obtained on said surface at said illuminated side of said silicon substrate and said anti-reflective layer is made of a material selected from a group consisting of silicon nitride, zinc oxide, tin oxide, indium tin oxide and silicon dioxide.

4. The solar cell according to claim 1,
wherein a passivation layer is obtained on said surface at said illuminated side of said silicon substrate and said passivation layer is made of a material selected from a group consisting of silicon dioxide, silicon nitride, silicon oxynitride, aluminum oxide, aluminum nitride and amorphous silicon.

5. The solar cell according to claim 1,
wherein both said first surface region and said second surface region at said illuminated side of said silicon substrate have light-trapping textured structures.

6. The solar cell according to claim 1,
wherein said second surface region at said illuminated side of said silicon substrate has a light-trapping textured structure and said first surface region does not have a light-trapping textured structure.

7. The solar cell according to claim 1,
wherein both said first doped layer and said second doped layer have an opposite doping polarity with respect to said silicon substrate.

8. The solar cell according to claim 1,
wherein both of said first doped layer and said second doped layer have the same doping polarity as said silicon substrate and have doping concentrations higher than said silicon substrate.

9. The solar cell according to claim 1,
wherein a back surface field and a back contact are obtained on a surface at the back side of said silicon substrate.

10. The solar cell according to claim 9,
wherein said back surface field is obtained by coating a doped layer on said surface at said back side of said silicon substrate.

11. The solar cell according to claim 10,
wherein said doped layer is made of a material selected from a group consisting of amorphous silicon, crystalline silicon, an amorphous silicon germanium compound and a crystalline silicon germanium compound.

12. The solar cell according to claim 9,
wherein said back surface field is obtained by high-temperature diffusion with a doping element and said doping element is selected from a group consisting of a III A group element and a V A group element

13. The solar cell according to claim 1,
wherein a passivation layer is obtained on a surface at the back side of said silicon substrate and said passivation layer is made of a material selected from a group consisting of silicon dioxide, silicon nitride, silicon oxynitride, aluminum oxide, aluminum nitride and amorphous silicon.
